(19) United States
(12) Patent Application Publication
(10) Pub. No.: US 2023/0197694 A1
(43) Pub. Date: Jun. 22, 2023

(54) LED STRUCTURE HAVING ASYMMETRIC FACE, METHOD OF MANUFACTURING DIRECT-CURRENT-DRIVABLE LED ELECTRODE ASSEMBLY USING THE SAME, AND DIRECT-CURRENT-DRIVABLE LED ELECTRODE ASSEMBLY MANUFACTURED THEREBY

(71) Applicant: Kookmin University Industry Academy Cooperation Foundation, Seoul (KR)

(72) Inventor: Young Rag DO, Seoul (KR)

(73) Assignee: Kookmin University Industry Academy Cooperation Foundation, Seoul (KR)

(21) Appl. No.: 18/083,319

(22) Filed: Dec. 16, 2022

(30) Foreign Application Priority Data
Dec. 17, 2021 (KR) 10-2021-0181879

(51) Int. Cl. H01L 25/075; H01L 33/62; H01L 33/20

(52) U.S. Cl. CPC H01L 25/0753; H01L 33/62; H01L 33/20; H01L 33/32

(57) ABSTRACT

The present disclosure relates to a light-emitting diode (LED) structure, and more particularly, to an LED structure having an asymmetric face, a method of manufacturing a direct-current-drivable LED electrode assembly using the same, and a direct-current-drivable LED electrode assembly manufactured thereby.

### CROSS-REFERENCE TO RELATED APPLICATION

This application claims priority to and the benefit of Korean Patent Application No. 2021-0181879, filed on Dec. 17, 2021, the disclosure of which is incorporated herein by reference in its entirety.

### BACKGROUND

### 1. Field of the Invention

The present disclosure relates to a light-emitting diode (LED) structure, and more particularly, to an LED structure having an asymmetric face, a method of manufacturing a direct-current-drivable LED electrode assembly using the same, and a direct-current-drivable LED electrode assembly manufactured thereby.

### 2. Discussion of Related Art

Micro-light-emitting diodes (Micro-LEDs) and nano-LEDs may implement an excellent feeling of color and high efficiency and may be eco-friendly materials, and thus are used as core materials for displays. In line with such market conditions, recently, research for developing shell-coated nano-cable LEDs through new nanorod LED structures or new manufacturing processes is being conducted. In addition, research on a protective film material is being conducted to achieve high efficiency and high stability of a protective film covering an outer surface of nanorods, or research and development of a ligand material advantageous for a subsequent process is also being conducted.

Further, in line with research in such material fields, research on a mounting technology for mounting independent individual micro-LEDs and nano-LEDs on electrodes having a nano- or micro-unit size is also being actively conducted because it is practically impossible to mount micro-LEDs and nano LEDs one by one on target portions on the electrodes with a pick-and-place technology.

As part of these studies, Korean Patent Publication No. 10-1436123 discloses a display manufactured through a method of dropping a solution mixed with nanorod-type LEDs on sub-pixels, and then self-aligning nanorod-type LED elements on electrodes by forming an electric field between two aligned electrodes to form the sub-pixels.

However, the disclosed technology has a technical limitation in that the LED elements may be driven only by applying alternating current (AC) power to two electrodes because one end, which is an n-type semiconductor side, and the other end, which is a p-type semiconductor side, of the rod-type LED element in a major-axis direction are inevitably aligned randomly on two different electrodes on the same plane.

Further, a rod-type LED element has a structure in which two different semiconductor layers and a photoactive layer are stacked in a major-axis direction, and since the disclosed technology is a technology in which the rod-type LED element having such a structure is inevitably mounted while lying on the horizontal electrodes, which are horizontally spaced apart from each other, in the major-axis direction, rather than being mounted upright in the major-axis direction on the electrodes, a display that emits light more strongly to a side surface than a front surface is inevitably manufactured, and thus it is difficult to implement a display having sufficient front luminance.

Accordingly, there is an urgent need to develop an LED material and LED alignment technology that may implement a direct-current-drivable LED electrode assembly by aligning a plurality of LED elements so that a direction in which two different semiconductor layers are aligned on an electrode is in any one direction while greatly improving the front luminance of the LED electrode assembly implemented by aligning the LED elements on the electrode in a direction in which two different semiconductor layers and a photoactive layer constituting the LED element are stacked.

### SUMMARY OF THE INVENTION

The present disclosure is directed to providing a light-emitting diode (LED) structure, in which a light-emitting area is large, efficiency degradation due to surface defects is minimized or prevented, an electron-hole recombination rate is optimized, it is suitable for ink formation, and an LED element may be mounted upright in a stacking direction of each layer constituting the LED element and may be mounted in contact with or adjacent to any one desired semiconductor layer on an electrode without additional configuration such as a magnetic layer for self-alignment or a change of a conventional LED element manufacturing method that etches and separates an LED element from an LED wafer, ink for a printing apparatus including the same, a method of manufacturing a direct-current-drivable LED electrode assembly using the same, and a direct-current-drivable LED electrode assembly manufactured thereby.

One aspect of the present disclosure provides a light-emitting diode (LED) structure having an asymmetric face, in which layers including a first conductive semiconductor layer, a photoactive layer, and a second conductive semiconductor layer are stacked in a first direction, and a first face and a second face face each other in the first direction, wherein the first face and the second face have a congruent shape, and have an asymmetric shape in which a symmetrical axis does not exist.

According to one embodiment of the present disclosure, any one of the first conductive semiconductor layer and the second conductive semiconductor layer may be an n-type Group III-nitride semiconductor layer and the other one thereof may be a p-type Group III-nitride semiconductor layer.

Further, a shape of each of the remaining faces of the LED structure except for the first face and the second face may be different from the shape of at least one of the first face and the second face.

Further, each of the first face and the second face may have an area of 0.20 μm² to 100 μm².

Further, a thickness that is a vertical distance between the first face and the second face may be in a range of 0.3 μm to 3.5 μm.

Further, the first conductive semiconductor layer may be an n-type Group III-nitride semiconductor layer, and an electron delay layer may be further included below the first conductive semiconductor layer so that the number of electrons and the number of holes recombined in the photoactive layer are balanced.

Further, the electron delay layer may include one or more selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene) and derivatives thereof, polyaniline, poly(3-alkylthiophene), and poly(paraphenylene).

Further, the first conductive semiconductor layer may be a doped n-type Group III-nitride semiconductor layer, and the electron delay layer may be a Group III-nitride semiconductor having a doping concentration lower than that of the first conductive semiconductor layer.

In addition, the LED structure may further include a protective film having a surface direction parallel to the first direction and configured to surround a side surface of the LED structure.

Further, the first conductive semiconductor layer may be an n-type Group III-nitride semiconductor layer, the second conductive semiconductor layer may be a p-type Group III-nitride semiconductor layer, and the LED structure may further include at least one functional film of a hole pushing film configured to surround exposed side surfaces of the second conductive semiconductor layer, or the exposed side surfaces of the second conductive semiconductor layer and exposed side surfaces of at least a portion of the photoactive layer, and move holes on the exposed side surface toward a center, and an electron pushing film configured to surround exposed side surfaces of the first conductive semiconductor layer and move electrons on the exposed side surface toward a center.

Further, the LED structure may further include at least one of a second electrode layer provided on the first conductive semiconductor layer and a first electrode layer provided on the second conductive semiconductor layer.

Another aspect of the present disclosure provides an ink composition for a printing apparatus including the plurality of LED structures having an asymmetric face according to the present disclosure.

Still another aspect of the present disclosure provides a method of manufacturing a direct-current-drivable light-emitting diode (LED) electrode assembly, the method including operation (1) of preparing an ink composition for a printing apparatus including the plurality of LED structures having an asymmetric face according to the present disclosure, operation (2) of forming an alignment guide member having a plurality of holes each passing therethrough so as to have the same shape as a first face of the LED structure on one or more lower electrodes, operation (3) of discharging the ink composition for a printing apparatus on the alignment guide member through the printing apparatus, operation (4) of aligning the plurality of LED structures by inserting a second face side end portion of each of the LED structures placed on the alignment guide member into the hole of the alignment guide member, and operation (5) of forming one or more upper electrodes on the plurality of aligned LED structures so as to be in contact with the first face of the LED structure.

According to one embodiment of the present disclosure, in operation (2), an area of each of the plurality of holes provided in the alignment guide member may be formed to be 1.01 to 1.50 times larger than an area of a second face of each of the LED structures.

Further, in operation (2), a partition wall may be further formed on the alignment guide member so as to surround a region in which the plurality of holes are formed, or to surround regions obtained by dividing the region into two or more regions.

Further, in operation (2), the hole may be formed in a region of the alignment guide member corresponding to a main surface of one lower electrode.

Further, in operation (1), the LED structure having an asymmetric face may be a rod-type structure elongated in a second direction perpendicular to the first direction with an aspect ratio of a major axis and a minor axis of 2:1 or more in each of the first face and the second face, in operation (2), the lower electrode may include a first lower electrode and a second lower electrode formed to be spaced apart from each other in a main surface direction by a predetermined interval, in operation (2), one hole provided in the alignment guide member may be formed through the alignment guide member so that a front-end second face portion and a rear-end second face portion of the LED structure are respectively disposed on the main surfaces of the adjacent first and second lower electrodes, and operation (4) may be performed by applying power to the first and second lower electrodes.

Further, operation (4) may be performed by radiating a sound wave one time or multiple times.

Further, a chemical bonding linker may be provided on any one or more of the second face of the LED structure, an inner surface of the hole, and a bottom surface of the hole, so that each of the LED structures aligned by being inserted into the hole through operation (4) is not separated from the hole.

Further, the method may further include heat-treating to improve electrical contact between the second face of the LED structure and the lower electrode, and depositing an insulating material to fill a space between each LED structure and the hole into which the LED structure is inserted and to planarize a space between the plurality of aligned LED structures, between operation (4) and operation (5).

Yet another aspect of the present disclosure provides a direct-current-drivable light-emitting diode (LED) electrode assembly comprising a plurality of LED structures having an asymmetric shape, in which layers including a first conductive semiconductor layer, a photoactive layer, and a second conductive semiconductor layer are stacked in a first direction, and a first face and a second face each other in the first direction, wherein the first face and the second face have a congruent shape, and have an asymmetric shape in which a symmetrical axis does not exist; one or more lower electrodes which is spaced apart from each other and one or more upper electrodes; and an alignment guide member disposed on the one or more lower electrodes and having a plurality of holes each passing therethrough so as to have the same shape as the first face of the LED structure, wherein each of the plurality of LED structures is aligned on the lower electrodes so that the second face thereof is in contact with a main surface of each of the one or more lower electrodes, by inserting a second face side end portion thereof into the hole of the alignment guide member, and the one or more upper electrodes are disposed on a first face side end portion of each of the plurality of aligned LED structures.

Further, the present disclosure provides a light source equipped with an LED structure having an asymmetric face according to the present disclosure.

Hereinafter, terms used in the present disclosure are defined.

In descriptions of embodiments of the present disclosure, it should be understood that when, a layer, region, or pattern is referred to as being “on,” “above,” “under,” or “below” a substrate, another layer, another region, or another pattern, the terminology of “on,” “above,” “under,” or “below” includes both the meanings of “directly” and “indirectly” “on,” “above,” “under,” or “below.”

On the other hand, it is informed that the present invention has been researched with the support of the following national R&D projects.

[National Research and Development Project 1 Supporting This Invention]

[Project Series Number] 1711130702

[Project Number] 2021R1A2C2009521

[Government Department Name] Ministry of Science and ICT

[Project Management Authority Name] Korea Evaluation Institute of Industrial Technology

[Research Program Name] Middle-level Researcher Support Project

[Research Project Name] Development of dot-LED Material and Display Source/Application Technology

[Contribution Ratio] 1/2

[Project Execution Organization Name] Kookmin University Industry Academic Cooperation Foundation

[Period Of Research] Mar. 1, 2021 to Feb. 28, 2022

[National Research and Development Project 2 Supporting This Invention]

[Project Series Number] 1415174040

[Project Number] 20016290

[Government Department Name] Ministry of Trade, Industry and Energy

[Project Management Authority Name] Korea Evaluation Institute of Industrial Technology

[Research Program Name] Electronic Components Industry Technology Development-Super Large Micro-LED Modular Display

[Research Project Name] Development of sub-micron blue light-emitting source technology for modular display

[Contribution Ratio] 1/2

[Project Execution Organization Name] Kookmin University Industry Academic Cooperation Foundation

[Period Of Research] Apr. 1, 2021 to Dec. 31, 2024

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a perspective view of a light-emitting diode (LED) structure having an asymmetric face according to one embodiment of the present disclosure;

FIG. 2 is a plan view illustrating a first face (A) and a second face (B) of the LED structure in a first direction according to FIG. 1;

FIGS. 3A to 3D are plan views each illustrating a first face (A) and a second face (B) of each of LED structures, which have various shapes, in the first direction, and FIG. 3A is a view illustrating an example of the first face (A) and the second face (B) without having a symmetrical axis, and FIGS. 3B to 3D are views illustrating an example of the first face (A) and the second face (B) having one or more symmetrical axes;

FIG. 4 is a cross-sectional view of an LED structure according to one embodiment of the present disclosure;

FIG. 5 is a cross-sectional view of an LED structure according to one embodiment of the present disclosure;

FIGS. 6 and 7(a)-7(c) are schematic views illustrating a mechanism in which an alignment surface and an alignment direction of an LED structure are controlled through an alignment guide member according to one embodiment of the present disclosure;

FIG. 8 is a schematic view corresponding to a comparative example of the present disclosure, and illustrates a possible alignment aspect when an LED structure having a symmetrical surface is inserted and aligned using an alignment guide member;

FIG. 9(a)-9(n) is a schematic process view illustrating a process of manufacturing an LED electrode assembly according to one embodiment of the present disclosure;

FIG. 10(a)-10(d) is a schematic view illustrating a process of applying a bonding force between an LED structure and a lower electrode through a chemical bonding linker as one method to prevent separation of the LED structure during a process of manufacturing an LED electrode assembly according to one embodiment of the present disclosure;

FIG. 11(a)-11(b) is a schematic view illustrating a process of mounting an LED structure using an electric field during a process of manufacturing an LED electrode assembly according to one embodiment of the present disclosure;

FIG. 12 is a plan view of one surface of an LED structure in a first direction, which is suitable for the process illustrated in FIG. 11; and

FIGS. 13 and 14 are schematic cross-sectional views of LED electrode assemblies according to various embodiments of the present disclosure.

### DETAILED DESCRIPTION OF EXEMPLARY EMBODIMENTS

Hereinafter, embodiments of the present disclosure will be described in detail with reference to the drawings such that those skilled in the art to which the present disclosure can easily carry out the present disclosure. The present disclosure may be implemented in several different forms, and are not limited to the embodiments described herein.

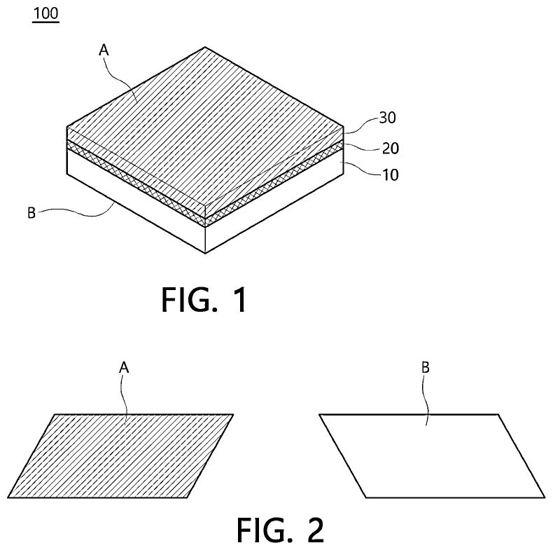

When described with reference to FIGS. 1 and 2, a light-emitting diode (LED) structure 100 according to the present disclosure is a structure in which layers including a first conductive semiconductor layer 10, a photoactive layer 20, and a second conductive semiconductor layer 30 are stacked in a first direction. In addition, in the LED structure 100 according to the present disclosure, a first face A and a second face B facing each other in the first direction have a congruent shape, but have an asymmetric shape in which a symmetrical axis does not exist.

Here, the first direction refers to a direction perpendicular to a main surface of each layer.

In addition, the shape of each of the first face A and the second face B refers to a shape of the face exposed to the outside of the LED structure 100, that is, a shape of a corresponding face shown when viewing the LED structure 100, and does not refer to an inverted shape corresponding to a virtual rear face of an exposed face (or a visible face). Here, the term “a certain shape has the same shape as that of the first face A or the second face B” refers to a case in which the certain shape is identical to the shape (or the shape as seen from the outside) of the first face A or the second face B exposed to the outside, that is, the certain shape is completely overlapped with the shape of the first face A or the second face when the certain shape is overlapped without inverting a front side and a back side thereof, and a case in which only an inverted surface is identical does not correspond to the case of the same shape.

Further, the term “congruence” refers to a case in which the sizes of the first face A and the second face B, which are flat faces, are equal to each other, and any one of the first face A and the second face B is completely overlapped with the other when the any one is overlapped with the other one as it is or by inverting front and back sides.

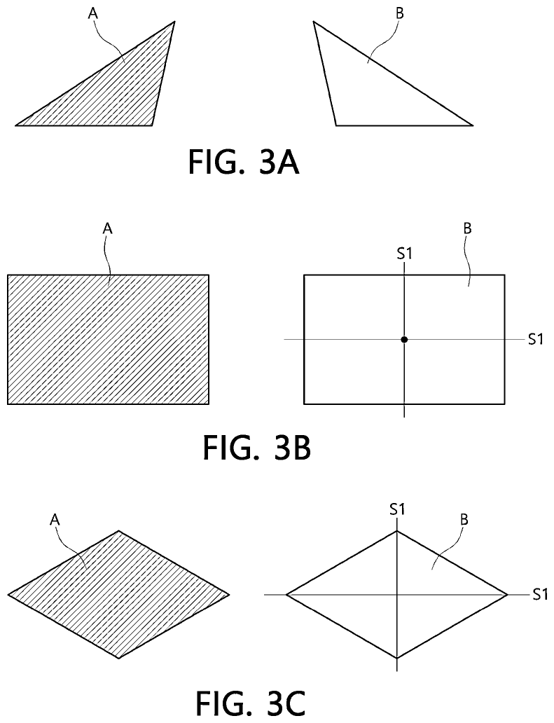

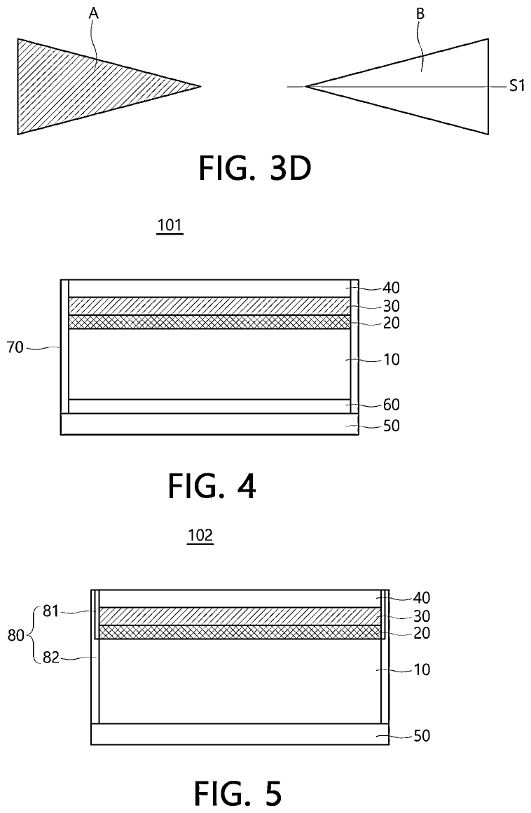

Further, the term “the first face A and the second face B are asymmetric faces having an asymmetric shape” refers to a face in which a symmetrical axis does not exist, and here, the term “axis of symmetry” refers to an axis that makes a half of a closed curve and the other half match each other when one face is folded based on one axis crossing the closed curve corresponding to a contour of the one face. For example, in the case of the first face A and the second face B illustrated in FIGS. 2 and 3A, a symmetrical axis does not exist because each of the first face A and the second face B is not symmetrical by any axis crossing a closed curve that is the outline of each of the first face A or the second face B. However, since each of the first face A and the second face B has two symmetrical axes S1 in the case of the first face A and the second face B having rectangular shapes illustrated in FIG. 3B, two symmetrical axes S1 in the case of the first face A and the second face B having rhombus shapes illustrated in FIG. 3C, and one symmetrical axis S1 in the case of the first face A and the second face B having isosceles triangle shapes illustrated in FIG. 3D, the first face A and the second face B correspond to symmetrical surfaces having a symmetrical shape.

Consequently, in the LED structure 100 shown in FIG. 1, the first face A and the second face B are asymmetric faces without having a symmetrical axis, and thus, the first face A and the second face B are in a congruent relationship in which a virtual image of the first face A is completely overlapped with the second face B. However, since the first face A and the second face B are overlapped with each other only when any one of the shape of the first face A and the shape of the second face B is inverted, it can be said that the shape of the first face A and the shape of the second face B are not identical to each other.

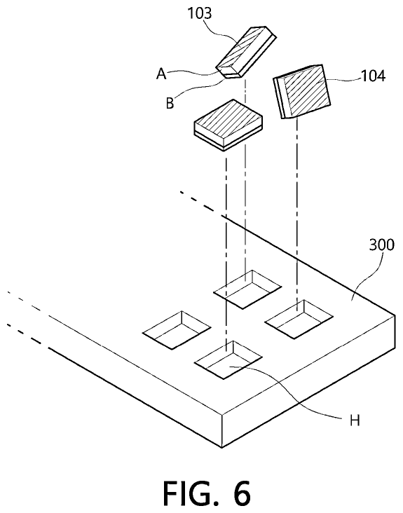

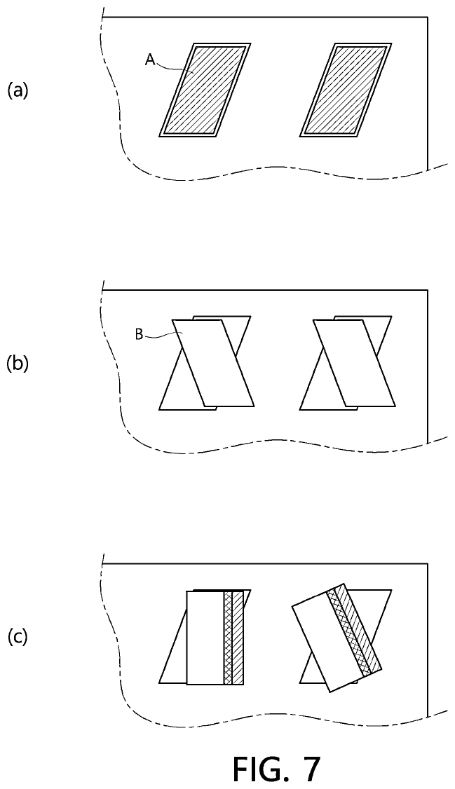

On the other hand, when the LED structure 100 is implemented such that the first face A and the second face B have shapes congruent with each other but have asymmetric shapes in which a symmetrical axis does not exist, the alignment surface and the alignment direction of each of the plurality of LED structures can be controlled with the help of the alignment guide member that has the hole passing therethrough so as to have the same shape as the shape of the first face A or the shape of the second face B. When describing this with reference to FIGS. 6 and 7(a)-7(c), as illustrated in the drawings, when a plurality of LED structures 103 and 104 are processed in an alignment guide member 300 having a plurality of holes H each passing therethrough so as to have the same shape as s shape of a first face A of each of the LED structures 103 and 104, only a second face B side end portion of each of the LED structures 103 and 104 can be inserted into the hole H as shown in FIG. 7(a), and a first face A side end portion of each of the LED structures 103 and 104, which has the same shape as an inverted shape thereof when viewed from the top of the alignment guide member 300, is not inserted into the hole H having the same shape as the first face A and passing through the alignment guide member 300.

Thus, when the plurality of LED structures are scattered on the lower electrodes through printing or the like and then self-aligned, the alignment surface of each of the LED structures aligned on the lower electrodes is controlled to be a specific surface, that is, the first face A or the second face B with the help of the alignment guide member 300 as described above, and in this case, all elements are aligned in the first direction on the lower electrode, thereby increasing top emission. In addition, all the first faces A or the second faces B of the LED structures can be aligned to be in contact with the lower electrode, so that the alignment direction of the LED structure can be controlled to be a specific direction of the first direction, thereby implementing an LED electrode assembly that can be driven by DC.

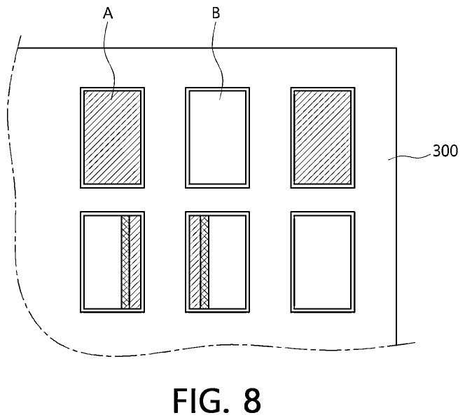

On the other hand, in the case of LED structures each having a first face A and a second face B of a rectangular shape having a symmetrical axis as shown in FIG. 3B, the first face A, the second face B, and remaining side surfaces may have a rectangular shape having a symmetrical axis. Accordingly, as shown in FIG. 8, since the LED structure may be inserted into the hole of the alignment guide member 300 such that any one surface of the first face A, the second face B, and the side surfaces becomes the alignment surface, even though the LED structures can be mounted on the lower electrode, some LED structures may be short circuited and may not emit light because the side surfaces thereof may be located on the lower electrode, and the remaining LED structures may be located on the lower electrode such that any one of the first face A and the second face B becomes the alignment surface, and thus, there may be a limitation in the selection of driving power, in which the LED electrode assembly cannot driven by DC power.

Further, according to one embodiment of the present disclosure, a shape of each of the remaining faces of the LED structure 100 except for the first face A and the second face B is different from the shape of at least one of the first face A and the second face B, and thus, when the LED structures 100 are randomly arranged on the lower electrode and then aligned, the case in which the LED structures 100 are aligned such that any one surface of the LED structure 100 other than the first face A and the second face B comes into contact with the lower electrode can be prevented. As an example, as shown in FIG. 7(c), a shape of a side surface of each of the LED structures 103 and 104 is a rectangular shape and is not the same as the shape of the first face A or the second face B, and accordingly, the side surface of each of the LED structures 103 and 104 cannot be inserted into the holes H of the alignment guide member 300, so that the side surface of each of the LED structures 103 and 104 may be prevented from becoming the alignment surface.

Meanwhile, the present disclosure does not particularly limit the shape of each of the remaining faces as long as the shape of each of the remaining faces of the LED structure 100 except for the first face A and the second face B is different from the shape of any one of the first face A and the second face B, and the shape of each of the remaining faces may be, for example, a rectangular shape, a square shape, or a parallelogram shape.

In addition, in the LED structures 100 described above, each of the first face A and the second face B may have an area of 0.20 μm² to 100 μm², and a thickness of the LED structure 100, which is a vertical distance between the first face A and the second face B, may be in a range of 0.3 μm to 3.5 μm, which may be advantageous for achieving the purpose of the present disclosure. Particularly, when the LED structure is manufactured so that the thickness thereof is 3.5 μm or less, as an example, a moving distance of holes and electrons passing through a p-type semiconductor layer and an n-type semiconductor layer corresponding to the second conductive semiconductor layer 30 and the first conductive semiconductor layer 10 may be significantly reduced, in particular, holes having very low mobility than electrons may move a shorter distance when moving, so that movement loss due to the movement distance can be minimized, thereby greatly improving light emission efficiency. However, when the thickness is less than 0.3 μm, the thickness of the n-type semiconductor layer may be relatively thinner than that of the p-type semiconductor layer, and thus a position at which electrons and holes are combined may deviate from the photoactive layer, thereby greatly reducing light emission efficiency.

Meanwhile, even when the thickness, which is the vertical distance between the first face A and the second face B, is within the preferred range described above, the position at which electrons and holes are combined may deviate from the photoactive layer due to a mobility difference between electrons and holes as described above. That is, when a large-area LED wafer is etched to implement the LED structures, thicknesses of the first conductive semiconductor layer, the photoactive layer, and the second conductive semiconductor layer are already determined in a state of the LED wafer, and only portions thereof are etched to a thickness different from a thickness of each of the layers in the wafer to implement the LED structure, and thus, such a problem inevitably occurs. Such a change in position at which electrons and holes are combined is caused due to a difference in velocity between electrons and holes moving in conductive semiconductor layers. As an example, in an n-type GaN conductive semiconductor layer, electrons have a mobility of 200 cm²/Vs, and in a p-type GaN conductive semiconductor layer, holes have a mobility of only 5 cm²/Vs, and thus, due to such an electron-hole velocity imbalance, a position at which electrons and holes are combined may vary according to a thickness of the p-type GaN conductive semiconductor layer and a thickness of the n-type GaN conductive semiconductor layer and may be formed by deviating from the photoactive layer.

In order to solve such a problem, as shown in FIG. 4, an LED structure 101 according to one embodiment of the present disclosure may be implemented to further include an electron delay layer 60 adjacent a lower portion of the first conductive semiconductor layer 10, when the first conductive semiconductor layer 10 is an n-type semiconductor layer so as to balance the numbers of holes and electrons recombined in the photoactive layer to prevent a degradation in light emission efficiency, and thus, even when a thickness of the first conductive semiconductor layer 10, which is an n-type semiconductor layer, is implemented to be thin, it is possible to prevent a degradation in light emission efficiency. In addition, the reduced thickness of the first conductive semiconductor layer 10 may decrease the probability that electrons are captured by surface defects while moving in a thickness direction of the first conductive semiconductor layer 10, thereby minimizing light emission loss and thus achieving greater light emission efficiency.

The electron delay layer 60 may include, for example, at least one selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene) and derivatives thereof, polyaniline, poly(3-alkylthiophene), and poly(paraphenylene). In addition, the electron delay layer 60 may have a thickness of 1 nm to 100 nm, but the present disclosure is not limited thereto, and the thickness of the electron delay layer 60 may be appropriately changed in consideration of a material of an n-type conductive semiconductor layer, a material of the electron delay layer, and the like.

Hereinafter, each layer constituting the LED structure 100 or 101 according to one embodiment of the present disclosure will be described in detail.

The LED structure 100 or 101 is formed by stacking layers including the first conductive semiconductor layer 10, the photoactive layer 20, and the second conductive semiconductor layer 30 in the first direction.

In this case, one of the first conductive semiconductor layer 10 and the second conductive semiconductor layer 30 may be an n-type semiconductor layer, and the other thereof may be a p-type semiconductor layer. A known semiconductor layer applied to an LED may be used as the n-type semiconductor layer and the p-type semiconductor layer without limitation. As an example, the n-type semiconductor layer and the p-type semiconductor layer may include Group III-V semiconductors referred to as Group III-nitride materials, in particular, binary, ternary, and quaternary alloys of gallium, aluminum, indium, and nitrogen.

As an example, the first conductive semiconductor layer 10 may be an n-type semiconductor layer, and in this case, the n-type semiconductor layer may include a semiconductor material having a composition formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, InN, and the like and may be doped with a first conductive dopant (for example, Si, Ge, Sn, or the like). According to one exemplary embodiment of the present disclosure, the first conductive semiconductor layer 10 may have a thickness of 100 nm to 3,000 nm, but the present disclosure is not limited thereto.

Further, the second conductive semiconductor layer 30 may be a p-type semiconductor layer, and in this case, the p-type semiconductor layer may include a semiconductor material having a composition formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, InN, and the like and may be doped with a second conductive dopant (for example, Mg). According to one exemplary embodiment of the present disclosure, the second conductive semiconductor layer 30 may have a thickness of 50 nm to 150 nm, but the present disclosure is not limited thereto.

Further, the photoactive layer 20 located between the first conductive semiconductor layer 10 and the second conductive semiconductor layer 30 may be formed to have a single or multi-quantum well structure. A photoactive layer included in a typical LED element used for lighting, a display, and the like may be used as the photoactive layer 20 without limitation. A clad layer (not shown) doped with a conductive dopant may be formed above and/or below the photoactive layer 20, and the clad layer doped with the conductive dopant may be implemented as, for example, an AlGaN layer or an InAlGaN layer. In addition, a material such as AlGaN or AlInGaN may also be used for the photoactive layer 20. In the photoactive layer 20, when an electric field is applied to an element, electrons and holes moving from the conductive semiconductor layers located above and below the photoactive layer to the photoactive layer are recombined to generate electron-hole pairs in the photoactive layer, thereby emitting light. According to one exemplary embodiment of the present disclosure, the photoactive layer 20 may have a thickness of 50 nm to 200 nm, but the present disclosure is not limited thereto.

Meanwhile, a second electrode layer 50 may be provided below the first conductive semiconductor layer 10 described above and/or a first electrode layer 40 may be further provided above the second conductive semiconductor layer 30.

An electrode layer included in a typical LED element used for lighting, a display, and the like may be used as the first electrode layer 40 and the second electrode layer 50 without limitation. The first electrode layer 40 and the second electrode layer 50 are each independently a single layer made of one selected from among Cr, Ti, Al, Au, Ni, ITO, and oxides or alloys thereof, a single layer made of two or more thereof, or a composite layer in which two or more materials thereof each constitute a layer. As an example, the LED structure may include a first electrode layer in which an ITO layer and a Ti/Au composite layer are stacked on the second conductive semiconductor layer 30. In addition, the first electrode layer 40 and the second electrode layer 50 may each independently have a thickness of 10 nm to 500 nm, but the present disclosure is not limited thereto.

In addition, the LED structure 101 may further include a protective film 70 covering the remaining faces except for the first face A and the second face B. The protective film 70 serves to protect surfaces of the first conductive semiconductor layer 10, the photoactive layer 20, and the second conductive semiconductor layer 30. In addition, in a process of etching an LED wafer in a thickness direction thereof and then separating a plurality of LED pillars, the protective film 70 may serve to protect the semiconductor layer including the first conductive semiconductor layer 10 and the photoactive layer. The protective film 70 may include, for example, at least one from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN). In addition, the protective film 70 may have a thickness of 5 nm to 100 nm and more preferably a thickness of 30 nm to 100 nm, which may be advantageous in protecting the first conductive semiconductor layer 10 corresponding to an n-type semiconductor layer in a process of separating the LED pillar formed after etching the LED wafer from the wafer body.

Meanwhile, as shown in FIG. 5, an LED structure 102 according to one embodiment of the present disclosure may include a functional film 80 that includes a hole pushing film 81 configured to surround exposed side surfaces of a second conductive semiconductor layer 30 or the exposed side surfaces of the second conductive semiconductor layer 30 and exposed side surfaces of at least a portion of a photoactive layer 20 to move holes on the exposed side surface toward a center, and an electron pushing film 82 configured to surround exposed side surfaces of a first conductive semiconductor layer 10 to move electrons on the exposed side surface toward a center in order to have a protection function as a protective film and also to improve light emission efficiency.

Specifically, when an n-type semiconductor layer is referred to as the first conductive semiconductor layer 10, some of the charges moving from the first conductive semiconductor layer 10 to the photoactive layer 20 and some of the holes moving from the second conductive semiconductor layer 30 to the photoactive layer 20 may move along a surface of a side surface of the LED structure, and in this case, quenching of electrons or holes may occur due to defects present on the surface, and thus, light emission efficiency may be degraded. In this case, even when a protective film surrounding the side surface of the LED structure is provided, quenching is unavoidable due to defects occurring at the surface of the side surface of the LED structure before the protective film is formed. However, when the functional film 80 includes the hole pushing film 81 and the electron pushing film 82, electrons and holes may be concentrated toward an element center and guided to move in a direction of the photoactive layer 20, and thus, even when defects are present on the surface of the side surface of the LED structure before the functional film 80 is formed, there is an advantage in that loss of light emission efficiency due to surface defects may be prevented.

The hole pushing film 81 may include, for example, at least one selected from the group consisting of AlN_{X}, ZrO₂, MoO, Sc₂O₃, La₂O₃, MgO, Y₂O₃, Al₂O₃, Ga₂O₃, TiO₂, ZnS, Ta₂O₅, and n-MoS₂, and the electron pushing film 82 may include at least one selected from the group consisting of Al₂O₃, HfO₂, SiNₓ, SiO₂, ZrO₂, Sc₂O₃, AlNₓ, and Ga₂O₃.

Further, as shown in FIG. 5, when the LED structure 102 includes both the hole pushing film 81 and the electron pushing film 82, the electron pushing film 82 may be provided as an outermost film surrounding side surfaces of the first conductive semiconductor layer 10, the photoactive layer 20, and the second conductive semiconductor layer 30.

Further, the hole pushing film 81 and the electron pushing film 82 may each independently have a thickness of 1 nm to 50 nm.

Meanwhile, it should be noted that the first conductive semiconductor layer 10, the photoactive layer 20, and the second conductive semiconductor layer 30, which are described above, may be included as minimum components of the LED structure, and another phosphor layer, a quantum dot layer, an active layer, a semiconductor layer, a hole blocking layer, and/or an electrode layer may be further included above/below each layer.

Since the above-described LED structure 100 or 101 according to one embodiment of the present disclosure may be manufactured by appropriately employing a known method for manufacturing individual isolated LED elements through an LED wafer, in the present disclosure, the manufacturing method of the LED structure 100 or 101 is not particularly limited. However, when an area of the first face A of the LED structure 100 or 101 is considered, the LED structures etched from the LED wafer may not be easily separated into individual structures when the LED structure 100 or 101 is manufactured to have a small thickness.

Accordingly, the LED structure 100 or 101 according to one embodiment of the present disclosure may be manufactured by including operation (A) of patterning an upper portion of an LED wafer, which is obtained by stacking at least an n-type semiconductor layer corresponding to a first conductive semiconductor layer, a photoactive layer, and a p-type semiconductor layer corresponding to a second conductive semiconductor layer, to have a desired shape of a first face A, and then vertically etching a first conductive semiconductor layer 10 to at least a partial thickness thereof to form a plurality of LED structures whose bottom surfaces are not separated from an LED wafer body, operation (B) of forming a protective film so as to surround an exposed surface of each of the plurality of LED structures but exposes an upper surface of the first conductive semiconductor layer located between the adjacent LED structures to the outside, operation (C) of immersing the LED wafer in an electrolyte, electrically connecting the LED wafer to one terminal of a power supply, electrically connecting the other electrode of the power supply to an electrode immersed in the electrolyte, and then applying power to form a plurality of pores in a portion of the first conductive semiconductor layer located below the plurality of LED structures that are not separated from the LED wafer body, and operation (D) of applying ultrasonic waves to the LED wafer to separate the plurality of LED structures from the portion of the first conductive semiconductor layer in which the plurality of pores are formed.

In this case, as patent documents by the inventor of the present disclosure, Korean Patent Application Nos. 10-2020-0189204 and 10-2020-0189203 are incorporated by reference in their entirety in the method of manufacturing the LED structure 100 or 101 including operations (A) to (D), and thus, detailed descriptions of the method of manufacturing the LED structure 100 or 101 including operations (A) to (D) will be omitted. When the LED structure is manufactured according to the above-described patent documents by the inventors of the present disclosure, the surface of the bottom surface of the separated LED structure can be easily and smoothly separated from the LED wafer body even when the LED structure is manufactured by increasing an area of the first face A and etching the LED structure to a relatively small thickness, or the first face A has a non-standardized shape, which may be advantageous for minimizing physical/chemical damage of the separated LED structure and obtaining the LED structure with minimal reduction in light emission efficiency.

Further, a method of manufacturing an LED structure having a functional film 80 as shown in FIG. 5 can also be performed by the above-described manufacturing method disclosed in the patent documents incorporated by reference herein, and a detailed description thereof will be omitted in the present disclosure.

The LED structures 100, 101, and 102 obtained by the above-described methods can be implemented as an ink composition for a printing apparatus. The ink composition may further include a dispersion medium and other additives that are provided in a known ink composition for a printing apparatus, and the present disclosure is not particularly limited thereto. In addition, the printing apparatus may be a known printing apparatus such as an inkjet printer, a 3D printer, a dispenser, or the like, and the present disclosure is not particularly limited thereto.

The above-described LED structure 100, 101, or 102 can be mounted on the electrode by controlling the alignment surface and the alignment direction thereof through a method to be described below, which will be described together with a method of manufacturing an electrode assembly having LED structures.

The LED electrode assembly according to one embodiment of the present disclosure may be manufactured by including operation (1) of preparing an ink composition (for a printing apparatus) including a plurality of LED structures each having an asymmetric face according to the present disclosure, operation (2) of forming an alignment guide member, which has a plurality of holes each passing therethrough so as to have the same shape as a first face of the LED structure, on at least one lower electrode, operation (3) of discharging the ink composition for a printing apparatus onto the alignment guide member through a printing apparatus, operation (4) of aligning the plurality of LED structures by inserting a second face side end portion of each of the LED structure placed on the alignment guide member into the hole of the alignment guide member, and operation (5) of forming at least one upper electrode on the plurality of aligned LED structures so as to be in contact with the first face of the LED structure, and the manufactured LED electrode assembly can be driven by DC because the plurality of LED structures can be aligned in one specific direction so that one surface of the LED structure on a specific conductive semiconductor layer side is located on the lower electrode.

First, operations (1) and (2) are operations that may be performed without being limited to the order, and in operation (1), the ink composition may be prepared to be suitable for a specific type of printing apparatus to be used as described above, and other additives, such as a dispersion medium that can help moving and aligning the LED structures after the LED structures are dispersed and discharged and a dispersing agent that can improve dispersibility may be further included in addition to the LED structure.

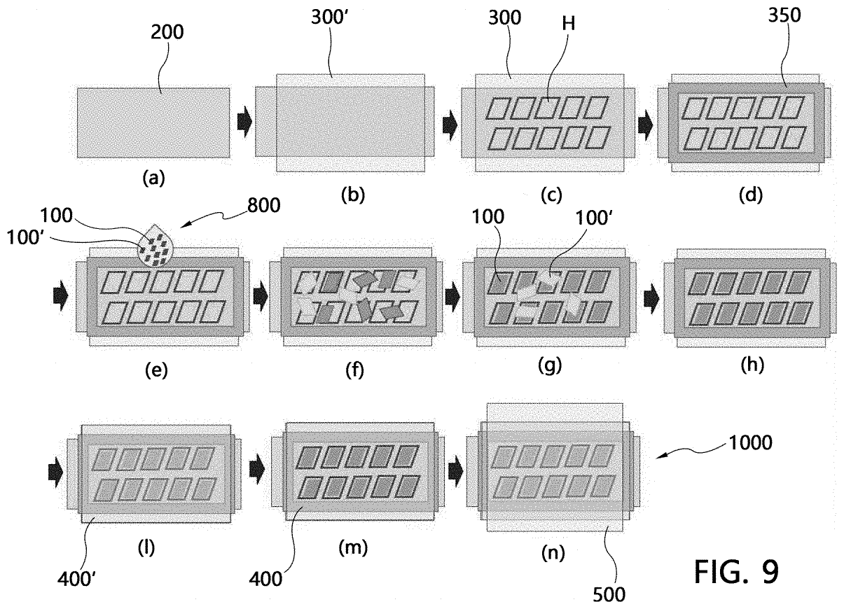

Further, operation (2) is an operation of preparing a region in which the LED structures are to be printed, and in operation (2), the alignment guide member having a plurality of holes each passing therethrough so as to have the same shape as the first face of the LED structure is formed on at least one lower electrode. When describing this with reference to FIG. 9(a)-9(n), a body 300′ of an alignment guide member is formed (see FIG. 9(b)) to a predetermined thickness on at least one lower electrode 200 as shown in FIG. 9A, and then a plurality of holes H each passing through the alignment guide member so as to have the same shape as a shape of a first face A of an LED structure 100 are formed, thereby forming an alignment guide member 300 (see FIG. 9(c)). The alignment guide member 300 may be made of an insulating material so as not to affect the driving of the mounted LED structure, and may include, for example, at least one from among silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN). In addition, the body 300′ of the alignment guide member, which is an origin of the alignment guide member 300, may be formed through a conventional deposition method. Here, the body 300′ of the alignment guide member to be deposited may have a thickness, for example, of 0.1 μm to 5.0 μm, and the thickness is not limited thereto, and the thickness may be appropriately changed in consideration of the thickness of the prepared LED structure.

Further, the holes H may be formed by forming a plurality of pattern layers on an upper surface of the body 300′ of the alignment guide member so as to have the same shape as the shape of the first face A of the LED structure, and then etching the pattern layers by a thickness of the body 300′ of the alignment guide member. Here, the pattern layer may be a pattern formed through photolithography using a photosensitive material, or formed through a known nano imprinting method, laser interference lithography, electron beam lithography, or the like. In addition, the etching may employ a suitable known etching method according to the material of the body 300′ of the alignment guide member, and for example, may be performed through a dry etching method using reactive ion etching (RIE).

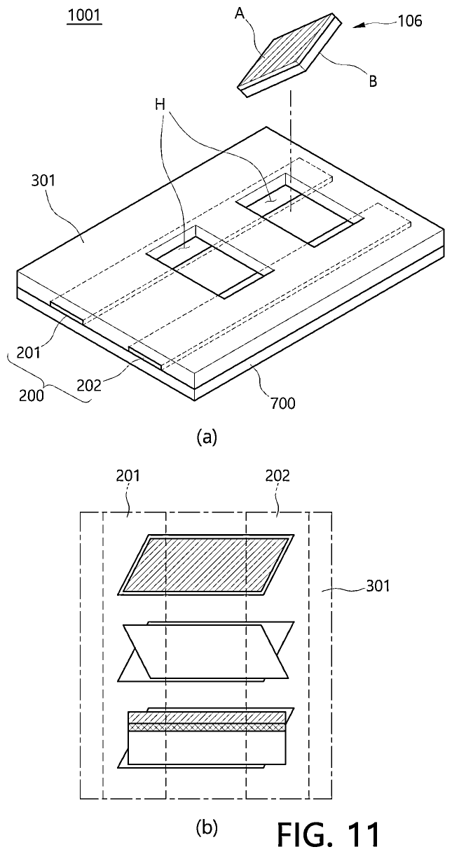

Further, the hole H may be formed in a region corresponding to a main surface of the lower electrode 200 such that at least a portion of the main surface of the lower electrode 200 is located inside the hole H. That is, the hole H may be changed in consideration of the shape and size of the LED structure, the width of the lower electrode, and the number of lower electrodes in contact with one surface of the LED structure. As an example, an LED structure 106 shown in FIG. 11(a)-11(b) is mounted such that one surface of the LED structure is in contact with main surfaces of both a first lower electrode 201 and a second lower electrode 202. In this case, a hole H of the alignment guide member 301 may be formed so that a portion of the main surface of the first lower electrode 201 and a portion of the second lower electrode 202 are present inside the hole H.

Meanwhile, the hole H may have the same shape as a shape of a first face A of the LED structure, and the hole H may have a size 1.01 to 1.50 times larger than an area of the first face A of the LED structure so that one end of the LED structure in the first direction is easily inserted thereinto. When the hole H is formed to have a size less than 1.01 times the area of the first face A, one end of the LED structure may be difficult to be inserted into the hole H, and thus, the time for performing operation (4) of aligning the LED structures may be extended, or the LED structures may not be disposed in some holes H in the alignment guide member 300 despite the extended time of operation (4). In addition, when the hole H is formed to have a size more than 1.50 times the area of the first face A, one end of the LED structure may be easily separated after one end of the LED structure is inserted and aligned in the hole H through operation (4).

Further, the hole H may be formed to preferably have a depth 0.5 to 1.5 times a thickness of the LED structure so that the LED structure inserted into the hole H is not separated from the hole H, which may be advantageous in that the insertion and alignment of one end of the LED structure is not inhibited while preventing the inserted and aligned LED structure from being separated from the hole H.

Meanwhile, according to one embodiment of the present disclosure, operation (2) may further include a process of forming a partition wall 350 surrounding a region, in which the plurality of holes H are formed, on the alignment guide member 300. The partition wall 350 may be formed as one so as to surround all of the plurality of holes H formed on the alignment guide member 300 (see FIG. 9(d)), or a region in which the plurality of holes H are formed may be divided into two or more regions, and the partition wall 350 may be formed to surround the divided regions. The partition wall may prevent a liquid ink composition from flowing into a part other than a desired region after the liquid ink composition is printed on the alignment guide member 300 so that the LED structures may be concentrated and placed around the plurality of holes H, and through this, the probability that the LED structures are inserted into all of the plurality of holes H can be increased. The partition wall 350 may be made of an insulating material so as not to provide an electrical influence when the LED structure is driven in a final LED electrode assembly implemented by mounting the LED structure therein. Preferably, the insulating material may use any one or more from among inorganic insulating materials, silicon dioxide (SiO₂), silicon nitride (Si₃N₄), aluminum oxide (Al₂O₃), hafnium oxide (HfO₂), yttrium oxide (Y₂O₃), and titanium dioxide (TiO₂), and various transparent polymer insulating materials. In addition, the partition wall 350 may be manufactured as the partition wall 350 by forming an insulating material on the alignment guide member 300 to have a thickness of the partition wall 350 and then performing a patterning and etching process to have a sidewall shape surrounding the plurality of holes H of the alignment guide member 300.

In this case, when the material is an inorganic insulating material, the partition wall 350 may be formed on the alignment guide member 300 by any one among a chemical vapor deposition method, an atomic layer deposition method, a vacuum deposition method, an e-beam deposition method, and a spin coating method. In addition, when the material is a polymer insulating material, the partition wall 350 may be formed on the alignment guide member 300 by a coating method such as spin coating, spray coating, or screen printing. In addition, the patterning may be performed by photolithography using a photosensitive material, or performed by a known nano imprinting method, laser interference lithography, electron beam lithography, or the like. At this point, a thickness of the insulating material, which will become the partition wall 350, is ½ or more of a thickness of the LED structure, and may be preferably in a range of 0.1 μm to 100 μm, and more preferably in a range of 0.3 μm to 10 μm as a thickness that may not normally affect post-processing. When the above-described range is not satisfied, which may affect a post process, and thus it may be difficult to manufacture an LED electrode assembly. In particular, when the thickness of the insulating material is too small compared to the thickness of the LED structure, the effect of preventing the overflow of the LED structures through the partition wall may be insufficiently achieved, and there is a risk that the ink composition including the LED structures may overflow out of the partition wall.

In addition, the etching may adopt a suitable etching method in consideration of the material of the insulating material, and may be performed by, for example, a wet etching method or a dry etching method. Preferably, the etching may be performed by one or more dry etching methods among plasma etching, sputter etching, reactive ion etching, and reactive ion beam etching.

Next, as operation (3) according to the present disclosure, discharging an ink composition 800 (for a printing apparatus) including a plurality of LED structures 100 and 100′ on the alignment guide member 300 through the printing apparatus is performed (see FIGS. 9(e) and 9(f)). Here, preferably, the ink composition 800 may be discharged to in the partition wall 350 described above.

Thereafter, as operation (4) according to the present disclosure, aligning the LED structure 100 by inserting one end of a first face A of each of the plurality of LED structures 100 and 100′ randomly placed on the alignment guide member 300 into the hole H of the alignment guide member 300 is performed (see FIG. 9(g)).

In operation (4), a method capable of easily changing and adjusting the position and direction of the LED structures 100 and 100′ such that a second face side end portion of each of the LED structures 100 and 100′ is inserted into the hole H formed in the alignment guide member 300 by moving the LED structures 100 and 100′ can be used without limitation for arranging the LED structures 100 and 100′. As an example, operation (4) may be performed by radiating a sound wave one time or multiple times, and specifically, the LED structure can be moved, inserted, and aligned in the holes H in such a manner that a sound wave is radiated by appropriately adjusting the frequency, waveform, and amplitude of the sound wave, or two or more types of sound waves, in which at least one of a frequency, a waveform, and an amplitude is different, are radiated together or sequentially in consideration of an interval of the holes H formed in the alignment guide member 300, the movement distance of the LED structure, and the like. The sound wave may be radiated through a conventional sound wave generator, and the present disclosure is not particularly limited thereto.

Further, in operation (4), the LED structures may be moved, inserted, and aligned in the holes H by applying vibration together with the sound wave described above or by applying vibration independently without the sound wave, and the intensity or period of the applied vibration may be appropriately adjusted in consideration of the interval between the holes H formed in the alignment guide member 300 or a movement distance of the LED structures, and thus the present disclosure is not particularly limited thereto.

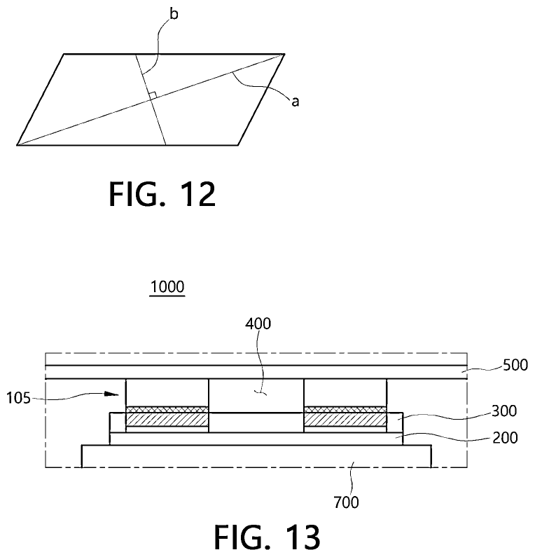

Alternatively, operation (4) may be performed by a conventional electric field induction method using an electric field. That is, when the shape of the LED structure elongated in one direction perpendicular to the first direction, the electric field induction method through electric field application may be more suitable. When describing this with reference to FIGS. 11(a)-11(b) and 12, when the LED structure 106 having an asymmetric face is a rod-type structure elongated in a second direction perpendicular to the first direction with an aspect ratio of a major axis a and a minor axis b of 2:1 or more in each of the first face A and the second face B, when an electric field is applied, both ends of the LED structure 106 are polarized to have different charges in the second direction, and thus, the LED structure may be mounted over the first lower electrode 201 and the second lower electrode 202, to which different power is applied, in the second direction. In this case, as illustrated in FIG. 11(b), the first face A, the second face B, and a side surface of the LED structure 106 may be aligned on the first lower electrode 201 and the second lower electrode 202 in the second direction, and when a second face B side end portion of the LED structure 106, which matches the shape of the hole H of the alignment guide member 301, is located over the electrodes in the second direction, the LED structure may be mounted so as to be inserted into the hole H, and in the other two cases, that is, when the first face A or the side surface is disposed adjacent to the first lower electrode 201 and the second lower electrode 202, the first face A or the side surface may not be inserted and mounted in the hole H, and thus, an alignment surface and an alignment direction of the LED structure 106 may be controlled. Here, the LED structure, which is not inserted and mounted in the hole H, may finally be inserted and aligned in the hole H so that the second face of the LED structure 106 becomes the alignment surface, by inducing additional direction change of the LED structure by changing the intensity or the like of the applied electric field, or additionally applying the vibration or sound wave together with the electric field. In this case, an intensity of power applied to form an electric field may be set within a known voltage range used in a magnetic alignment process using an electric field, and the intensity of the power may be appropriately changed in consideration of the aspect ratio or size of the LED structure, and thus the present disclosure is not particularly limited thereto.

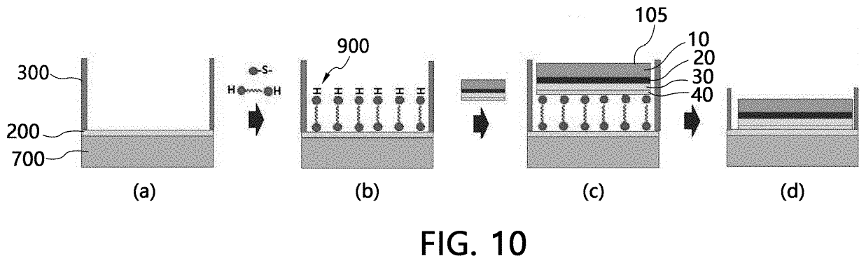

Meanwhile, there is a concern that the LED structure, whose one end is inserted and aligned in the hole H of the alignment guide member 300 or 301 prior to the other LED structures in the process of performing operation (4), or the LED structure, which is inserted and aligned in the hole H through operation (4) may be separated from the hole H in a process of aligning the other LED structures that are not aligned, or in a process of performing a subsequent process. According to one embodiment of the present disclosure, in order to prevent the separation of the inserted and aligned LED structure, as shown in FIG. 10(a)-10(b), forming a chemical bonding linker 900 on the lower electrode 200 formed on a substrate 700 may be further performed before operation (3) (see FIGS. 10(a) and 10(b)). The chemical bonding linker 900 is for providing a bonding force between a first electrode layer 40 of an LED structure 105 and the lower electrode 200 by inducing a chemical bond, and may be formed such that, for example, a thiol group, an amine group, a carboxyl group, single strand DNA or the like may be exposed to the outside. Specifically, the chemical bonding linker 900 may be formed through a compound such as aminoethanethol, 1,2-ethanedithiol, 1,4-butanedithiol, 3-mercaptopropionic acid, NH₂-terminated single-stranded DNA, or the like. In addition, the chemical bond may be a covalent bond or a non-covalent bond, and for example, when a thiol group is used as the chemical bonding linker, a non-covalent bond between the lower electrode 200 and/or the first electrode layer 40, which is a metal, may be induced to provide a bonding force (see FIGS. 10(c) and 10(d)).

Meanwhile, in some cases, the chemical bonding linker may also be formed on the second face B of the LED structure differently from that shown in FIG. 10(a)-10(d), and a bonding force may be applied between the LED structure 105 and the lower electrode 200 through a complementary bond between a first chemical bonding linker formed on the lower electrode 200 and a second chemical bonding linker formed on the second face B of the LED structure. As an example, the first chemical bonding linker and the second chemical bonding linker may be an amine group and a carboxyl group, respectively, and an amide bond may be formed by bonding the amine group with the carboxyl group. However, since a reaction rate is low when the amide bond is formed by bonding the amine group with the carboxyl group, 1-ethyl-3-(3-dimethylaminopropyl)carbodiimide (EDC) may be added to form an active ester intermediate of the carboxyl group, followed by addition of a strong nucleophilic primary amine, thereby rapidly forming the amide bond. In addition, in order to stabilize the ester intermediate using EDC, sulfo N-Hydroxysuccinimide (NHS) may be used so that the amide bond may be stably performed.

Further, after operation (4) is performed and before operation (5) to be described below is performed, washing the LED structure 101′ that is not inserted and aligned may be performed (see FIG. 9(g)), and through this, an intermediate structure, in which the LED structure 100 is inserted and aligned in the hole H formed in the alignment guide member 300, may be implemented (see FIG. 9(h)).

Thereafter, in the intermediate structure, heat-treating to improve electrical contact between the second face B of the LED structure 100 and the lower electrode 200 and depositing the insulating layer 400 to fill a space between each LED structure 100 and the hole H into which the LED structure 100 is inserted and to planarize a space between the plurality of aligned LED structures 100 may be further performed (see FIGS. 9(l) and 9(m)) before operation (5) to be described below.

First, the heat treating performed to improve electrical contact between the second face B of the LED structure 100 and the lower electrode 200 is an operation to achieve an ohmic contact therebetween, and for example, the heat treating may be performed by performing a rapid thermal annealing (RTA) process on interfaces between the lower electrode 200 and the second face B of the LED structure. The RTA may be performed through a known RTA process performed to achieve an ohmic contact, and the present disclosure is not particularly limited thereto.

Further, the depositing (see FIGS. 9(l) and 9(m)) of the insulating material to fill the space between each LED structure 100 and the hole into which the LED structure 100 is inserted and to planarize the space between the plurality of aligned LED structures 100 is an operation of forming an insulating layer 400 to a predetermined thickness on the alignment guide member 300 for electrical insulation from an upper electrode 500 to be formed in operation (5) to be described below. The insulating layer 400 may be formed through deposition of a known insulating material, for example, by depositing an insulating material such as SiO₂ or SiNₓ through a plasma-enhanced chemical vapor deposition (PECVD) method, or depositing an insulating material such as AlN or GaN through a metal-organic chemical vapor deposition (MOCVD) method, or depositing an insulating material such as Al₂O, HfO₂, or ZrO₂ through an atomic layer deposition (ALD) method. Meanwhile, it is preferable that the insulating layer 400 is formed so as not to cover a surface of the first face A of the LED structure 100, which is inserted and aligned, and to this end, the insulating layer 400 may be formed through deposition to a thickness that does not cover the surface of the first face A of the LED structure 100, or, after depositing an insulating layer 400′ to a thickness covering the surface of the first face A of the LED structure 100 (see FIG. 9(l)), dry etching may be performed until the surface of the first face A of the LED structure 100 is exposed (see FIG. 9(m)).

Thereafter, as operation (5) according to the present disclosure, forming at least one upper electrode 500 on the plurality of aligned LED structures 100 so as to be in contact with the first face A of the LED structure 100 is performed to implement an LED electrode assembly 1000. The upper electrode 500 may be implemented by depositing an electrode material after patterning an electrode line using known photolithography, or by depositing an electrode material and then performing dry and/or wet etching. Here, the electrode material may be a typical electrode material used as an electrode of an electrical/electronic material, and the present disclosure is not particularly limited thereto.

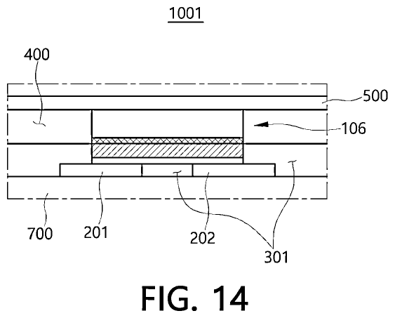

Referring to FIGS. 13 and 14, LED electrode assemblies 1000 and 1001 manufactured through one embodiment of the present disclosure respectively include a plurality of LED structures 105 and a plurality of LED structures 106 having an asymmetrical shape according to one embodiment of the present disclosure, one or more lower electrodes 200 and one or more lower electrodes 201 and 202 that are spaced apart from each other in the first direction, one or more upper electrodes 500 and one or more upper electrodes 500 spaced apart from each other in the first direction, an alignment guide member 300 and an alignment guide member 301, which are respectively disposed on the one or more lower electrodes 200 and the one or more lower electrodes 201 and 202 and each of which has a plurality of holes H each passing therethrough so as to have the same shape as a first face A of each of the plurality of LED structures 105 and the plurality of LED structures 106, and the LED electrode assemblies 1000 and 1001 are implemented such that each of the plurality of LED structures 105 and each of the plurality of LED structures 106 are aligned respectively on the lower electrodes 200 and the lower electrodes 201 and 202 such that a second face B each thereof is in contact with a main surface of each of the lower electrodes 200, 201, and 202 by inserting a second face B side end portion each thereof into the hole H of each of the alignment guide members 300 and 301, and one or more upper electrodes 500 are disposed on first face A side end portions off the plurality of aligned LED structures 105 and 106. The LED electrode assemblies 1000 and 1001 according to the present disclosure are aligned such that a specific surface of each of the plurality of mounted LED structures 105 and each of the plurality of mounted LED structures 106, for example, the second face B, are respectively in contact with the lower electrodes 200 and the lower electrodes 201 and 202, and thus can be driven by applying DC power, and the LED electrode assemblies 1000 and 1001 have an advantage in that front luminance can be greatly increased as the first direction of the LED structures 105 and 106 corresponds to a front surface.

In addition, the present disclosure includes a light source having the above-described LED structure 101, 102, 103, 104, 105, or 106. The light source may include, for example, various LED lights for home/vehicle, light-emitting sources of various displays, such as backlight units used in liquid crystal displays (LCDs) and light-emitting sources of active displays, medical devices, beauty devices, various optical devices, or one component constituting the same.

The present disclosure will be described in more detail through the following Example. However, the following Example is only for illustrating the present disclosure and the scope of the present disclosure is not limited thereto.

### EXAMPLE 1

A typical LED wafer (manufactured by Epistar), in which an undoped n-type Group III-nitride semiconductor layer, an n-type Group III-nitride semiconductor layer doped with Si (with a thickness of 4 μm), a photoactive layer (with a thickness of 0.45 μm), and a p-type Group III-nitride semiconductor layer (with a thickness of 0.05 μm) are sequentially stacked on a substrate, was prepared. ITO (with a thickness of 0.15 μm) as a first electrode layer, SiO₂ (with a thickness of 1.2 μm) as a first mask layer, and Al (with a thickness of 0.2 μm) as a second mask layer were sequentially deposited on the prepared LED wafer, and then a spin-on-glass (SOG) resin layer onto which a pattern is transferred in a shape of the first face A as shown in FIG. 2 to become an asymmetric face was transferred onto the second mask layer using nanoimprint equipment. Thereafter, the SOG resin layer was cured using RIE, and a residual resin portion of the resin layer was etched through RIE to form a resin pattern layer. Thereafter, the second mask layer was etched along the pattern using ICP, and the first mask layer was etched using RIE. Subsequently, after the first electrode layer, the p-type Group III-nitride semiconductor layer, and the photoactive layer were etched using ICP, the doped n-type Group III-nitride semiconductor layer was etched to a thickness of 0.78 μm, and then, an LED wafer, on which a plurality of LED structures (with an area S of an first face A of 1.77 μm² and a etch depth of 500 nm) are formed through KOH wet etching so that a side surface of the etched doped n-type Group III-nitride semiconductor layer is perpendicular to a layer surface, was manufactured. Thereafter, a SiNₓ protective film material was deposited on the LED wafer on which the plurality of LED structures are formed (deposition thicknesses of 52.5 nm and 72.5 nm based on a side surface of the LED structure), and then, the protective film material formed between the plurality of LED structures was removed using a reactive ion etcher to expose an upper surface of the doped n-type Group III-nitride semiconductor layer corresponding to a portion between the LED structures.

Thereafter, the LED wafer on which a temporary protective film was formed was immersed in an electrolyte which is a 0.3M oxalic acid solution and connected to an anode terminal of a power supply, a cathode terminal was connected to a platinum electrode immersed in the electrolyte, and then, a voltage of 10 V was applied for 5 minutes to form a plurality of pores from a surface of a first portion a of the doped n-type Group III-nitride semiconductor layer to a depth of 600 nm. Thereafter, after the temporary protective film was removed through RIE, a Al₂O₃ surface protective film was deposited again on the LED wafer to a thickness of 50 nm based on the side surface of the LED structure, the surface protective film formed on the plurality of LED structures and the protective film formed on the surface of the doped n-type Group III-nitride semiconductor layer corresponding to the portion between the LED structures were removed through ICP to expose an upper surface S1 of the doped n-type Group III-nitride semiconductor layer corresponding to the portion between the LED structures and an upper surface of the LED structure. Thereafter, after the LED wafer was immersed in a bubble-forming solution of gamma-butyllactone, ultrasonic waves were radiated at a frequency of 40 kHz for 10 minutes to collapse the pores formed in the doped n-type Group III-nitride semiconductor layer using generated bubbles and separate the plurality of LED structures from the wafer, thereby manufacturing an LED structure aggregate including LED structures. Meanwhile, it was confirmed through a scanning electron microscope (SEM) image that non-separated LED structures do not exist on the remaining wafer after the separation process.

According to the present disclosure, a light-emitting diode (LED) structure can be mounted on an electrode in only one direction by controlling a geometric structure of the LED structure without changing a conventional manufacturing process of etching an LED wafer and manufacturing individual LED elements, so that an LED electrode assembly that can be driven by direct current (DC) can be easily manufactured, and the LED structure can be mounted on the electrode in a stacking direction of semiconductor layers constituting the LED structure, so that the LED electrode assembly with improved a top emission characteristic can be easily manufactured. In addition, the LED structure is advantageous in increasing a light-emitting area due to a structure thereof as compared to a conventional rod-type LED element, allows an area of a photoactive layer exposed to the surface to be greatly reduced while the light-emitting area is increased so that efficiency degradation due to surface defects can be prevented or minimized, and can minimize the situation in which electron-hole recombination efficiency is lowered due to an electron-hole velocity imbalance and thus light emission efficiency is lowered, thereby exhibiting a higher luminance. Accordingly, due to the advantages as described above, the LED structure according to the present disclosure can be widely applied as materials of various light sources such as lighting, medical devices, displays, and the like.

While the embodiments of the present disclosure have been described above, the present disclosure is not limited to the embodiments presented herein. One skilled in the art may easily suggest other embodiments due to addition, modification, deletion, and the like of components within the scope and spirit of the present disclosure, and the addition, modification, deletion, and the like of the components fall within the scope and spirit of the present disclosure.

What is claimed is:

1. A light-emitting diode (LED) structure having an asymmetric face, in which layers including a first conductive semiconductor layer, a photoactive layer, and a second conductive semiconductor layer are stacked in a first direction, and a first face and a second face face each other in the first direction,
wherein the first face and the second face have a congruent shape, and have an asymmetric shape in which a symmetrical axis does not exist.

2. The LED structure of claim 1, wherein a shape of each of the remaining faces of the LED structure except for the first face and the second face is different from the shape of at least one of the first face and the second face.

3. The LED structure of claim 1, wherein each of the first face and the second face has an area of 0.20 μm² to 100 μm².

4. The LED structure of claim 1, wherein a thickness that is a vertical distance between the first face and the second face is in a range of 0.3 μm to 3.5 μm.

5. The LED structure of claim 1, wherein
the first conductive semiconductor layer is an n-type Group III-nitride semiconductor layer, and
an electron delay layer is further included below the first conductive semiconductor layer so that the number of electrons and the number of holes recombined in the photoactive layer are balanced.

6. The LED structure of claim 5, wherein the electron delay layer includes one or more selected from the group consisting of CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene) and derivatives thereof, polyaniline, poly(3-alkylthiophene), and poly(paraphenylene).

7. The LED structure of claim 5, wherein
the first conductive semiconductor layer is a doped n-type Group III-nitride semiconductor layer, and
the electron delay layer is a Group III-nitride semiconductor having a doping concentration lower than that of the first conductive semiconductor layer.

8. The LED structure of claim 1, further comprising a protective film having a surface direction parallel to the first direction and configured to surround a side surface of the LED structure.

9. The LED structure of claim 1, wherein
the first conductive semiconductor layer is an n-type Group III-nitride semiconductor layer,
the second conductive semiconductor layer is a p-type Group III-nitride semiconductor layer, and
the LED structure further includes at least one functional film of a hole pushing film configured to surround exposed side surfaces of the second conductive semiconductor layer, or the exposed side surfaces of the second conductive semiconductor layer and exposed side surfaces of at least a portion of the photoactive layer, and move holes on the exposed side surface toward a center, and
an electron pushing film configured to surround exposed side surfaces of the first conductive semiconductor layer and move electrons on the exposed side surface toward a center.

10. The LED structure of claim 1, further comprising at least one of a second electrode layer provided on the first conductive semiconductor layer and a first electrode layer provided on the second conductive semiconductor layer.

11. An ink composition for a printing apparatus including the plurality of LED structures having an asymmetric face of claim 1.

12. A method of manufacturing a direct-current-drivable light-emitting diode (LED) electrode assembly, the method comprising:
operation (1) of preparing an ink composition for a printing apparatus including the plurality of LED structures having an asymmetric face of claim 1;
operation (2) of forming an alignment guide member having a plurality of holes each passing therethrough so as to have the same shape as the first face of the LED structure on one or more lower electrodes;
operation (3) of discharging the ink composition for a printing apparatus on the alignment guide member through the printing apparatus;
operation (4) of aligning the plurality of LED structures by inserting a second face side end portion of each of the LED structures placed on the alignment guide member into the hole of the alignment guide member; and
operation (5) of forming one or more upper electrodes on the plurality of aligned LED structures so as to be in contact with the first face of the LED structure.

13. The method of claim 12, wherein in operation (2), an area of each of the plurality of holes provided in the alignment guide member is formed to be 1.01 to 1.50 times larger than an area of a second face of each of the LED structures.

14. The method of claim 12, wherein in operation (2), a partition wall is further formed on the alignment guide member so as to surround a region in which the plurality of holes are formed, or to surround regions obtained by dividing the region into two or more regions.

15. The method of claim 12, wherein in operation (2), the hole is formed in a region of the alignment guide member corresponding to a main surface of one lower electrode.

16. The method of claim 12, wherein
in operation (1), the LED structure having an asymmetric face is a rod-type structure elongated in a second direction perpendicular to the first direction with an aspect ratio of a major axis and a minor axis of 2:1 or more in each of the first face and the second face,
in operation (2), the lower electrode includes a first lower electrode and a second lower electrode formed to be spaced apart from each other in a main surface direction by a predetermined interval,
in operation (2), one hole provided in the alignment guide member is formed through the alignment guide member so that a front-end second face portion and a rear-end second face portion of the LED structure are respectively disposed on the main surfaces of the adjacent first and second lower electrodes, and
operation (4) is performed by applying power to the first and second lower electrodes.

17. The method of claim 12, wherein operation (4) is performed by radiating a sound wave one time or multiple times.

18. The method of claim 12, wherein a chemical bonding linker is provided on any one or more of the second face of the LED structure, an inner surface of the hole, and a bottom surface of the hole, so that each of the LED structures aligned by being inserted into the hole is not separated from the hole.

19. The method of claim 12, further comprising: between operation (4) and operation (5),
heat-treating to improve electrical contact between the second face of the LED structure and the lower electrode; and
depositing an insulating material to fill a space between each LED structure and the hole into which the LED structure is inserted and to planarize a space between the plurality of aligned LED structures.

20. A direct-current-drivable light-emitting diode (LED) electrode assembly comprising:
a plurality of LED structures having an asymmetric shape, in which layers including a first conductive semiconductor layer, a photoactive layer, and a second conductive semiconductor layer are stacked in a first direction, and a first face and a second face each other in the first direction, wherein the first face and the second face have a congruent shape, and have an asymmetric shape in which a symmetrical axis does not exist;
one or more lower electrodes which is spaced apart from each other and one or more upper electrodes; and
an alignment guide member disposed on the one or more lower electrodes and having a plurality of holes each passing therethrough so as to have the same shape as the first face of the LED structure,
wherein each of the plurality of LED structures is aligned on the lower electrodes so that the second face thereof is in contact with a main surface of each of the one or more lower electrodes, by inserting a second face side end portion thereof into the hole of the alignment guide member, and
the one or more upper electrodes are disposed on a first face side end portion of each of the plurality of aligned LED structures.
